(19) United States
(12) Patent Application Publication
(10) Pub. No.: US 2026/0025104 A1
(43) Pub. Date: Jan. 22, 2026

(54) CONFIGURABLE RADIO FREQUENCY (RF) POWER AMPLIFIER (PA) CIRCUITRY FOR EFFICIENCY AT MULTIPLE OUTPUT POWER LEVELS, INCLUDING RELATED APPARATUSES AND METHODS

(71) Applicant: Microchip Touch Solutions Limited, Wokingham (GB)

(72) Inventors: Mohammad Mehrjoo, San Diego, CA (US); Pierre Henri Bousseaud, Cambridge (GB); Wei Cheng Liao, Zhubei (TW); Hyunchul Kim, San Diego, CA (US); Omid Rajaee, San Diego, CA (US); Chen Chen, Irvine, CA (US); Edwin Chiem, San Diego, CA (US); Farshad Sedaratioliaie, Irvine, CA (US); Saeed Pourbagheri, Poway, CA (US); Rahim Bagheri, Poway, CA (US)

(21) Appl. No.: 19/254,377

(22) Filed: Jun. 30, 2025

Related U.S. Application Data
(60) Provisional application No. 63/672,171, filed on Jul. 16, 2024.

(51) Int. Cl. H03F 1/02; H03F 1/56; H03F 3/24; H03F 3/45

(52) U.S. Cl. CPC H03F 1/0227; H03F 1/56; H03F 3/245; H03F 3/45179; H03F 2200/451

(57) ABSTRACT

An apparatus comprises a configurable radio frequency (RF) power amplifier (PA) circuitry including a first RF PA, a second RF PA, enable switches, a voltage source switch, and a logic circuitry. The first RF PA includes a first amplifier input coupled to an RF signal input. The second RF PA includes a second amplifier input coupled to the RF signal input. The second RF PA is in parallel with the first RF PA. The enable switches are for switchably enabling one of the first RF PA or the second RF PA. The voltage source switch is for switchably coupling one of a first voltage source or a second voltage source to a voltage bias input of an enabled one the first RF PA or the second RF PA. The first voltage source has a first voltage and the second voltage source has a second voltage greater than the first voltage.

### CROSS-REFERENCE TO RELATED APPLICATIONS

This application claims the benefit of the priority date of U.S. Provisional Patent Application No. 63/672, 171, filed Jul. 16, 2024, and titled “Reconfigurable Power Amplifier (PA) For High Efficiency At Multiple Output Powers, Including Related Apparatuses, Methods, And Systems,” the disclosure of which is incorporated herein in its entirety by this reference.

### TECHNICAL FIELD

Examples relate, generally, to radio frequency (RF) power amplifier (PA) circuitry. More specifically, some examples relate to configurable RF PA circuitry of RF transmitters, without limitation.

### BACKGROUND

Existing radio frequency (RF) power amplifiers (PAs) on the market target high efficiency operation at a single output power level. As the output power level is backed off, the RF PA efficiency degrades. The inventors of this disclosure appreciate that such an approach adversely impacts the life of the battery that powers the RF PA. For each RF PA, the target output power level at which performance is optimized is chosen in advance, and therefore the performance of the RF PA at other output power levels is less than optimal.

### BRIEF DESCRIPTION OF THE DRAWINGS

While this disclosure concludes with claims particularly pointing out and distinctly claiming specific examples, various features and advantages of examples within the scope of this disclosure may be more readily ascertained from the following description when read in conjunction with the accompanying drawings, in which:

FIG. 1 is a schematic diagram of a configurable radio frequency (RF) power amplifier (PA) circuitry for use in an RF transmitter, according to one or more examples;

FIG. 2 is a schematic diagram of a configurable RF PA circuitry for use in an RF transmitter, according to one or more further examples;

FIG. 3 is a schematic diagram of a voltage control circuitry of the configurable RF PA circuitry of FIG. 1 or FIG. 2, according to one or more examples;

FIG. 4 is a schematic diagram of a cascade circuit which may be used in the RF PAs of FIG. 1 or FIG. 2, according to one or more examples;

FIG. 5 is a schematic diagram of an RF receiver portion which may be coupled to the configurable RF PA circuitry of the disclosure, according to one or more examples;

FIG. 6 is a diagram to illustrate example multiple configurations of a configurable RF PA circuitry, according to one or more examples;

FIG. 7 is a graph of plots of simulation results indicating RF PA efficiency versus power output over multiple configurations of a configurable RF PA circuitry, according to one or more examples; and

FIG. 8 is a flowchart of a method of configuring a configurable RF PA circuitry to amplify according to a requested output power level, according to one or more examples.

### DETAILED DESCRIPTION

In the following detailed description, reference is made to the accompanying drawings, which form a part hereof, and in which are shown, by way of illustration, specific examples of examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example of this disclosure to the specified components, steps, features, functions, or the like.

It will be readily understood that the components of the examples as generally described herein and illustrated in the drawing could be arranged and designed in a wide variety of different configurations. Thus, the following description of various examples is not intended to limit the scope of the present disclosure but is merely representative of various examples. While the various aspects of the examples may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be depicted by block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. For example, data, instructions, commands, information, signals, bits, and symbols that may be referenced throughout this description may be represented by voltages, currents, electromagnetic waves, magnetic fields or particles, optical fields or particles, or any combination thereof. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal. A person having ordinary skill in the art would appreciate that this disclosure encompasses communication of quantum information and qubits used to represent quantum information.

The various illustrative logical blocks, modules, and circuits described in connection with the examples disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer is configured to execute computing instructions (e.g., software code) related to examples of the present disclosure.

The examples may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, or a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

In this description the term “coupled” and derivatives thereof may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. In this description, the term “connected” is used interchangeably with the term “coupled,” and has the same meaning, unless expressly indicated otherwise or the context would indicate otherwise to a person having ordinary skill in the art.

Existing RF PAs on the market target high efficiency operation at a single output power level. As the output power level is backed off, the RF PA efficiency degrades. Such an approach adversely impacts the life of a battery that powers the RF PA. For each RF PA, a target output power level at which performance is best is chosen in advance, and therefore the performance of the RF PA at other output power levels is typically less than optimal.

According to one or more examples, an RF PA circuitry of the disclosure is designed to be configurable to deliver acceptable, even optimal, performance at respective ones of different output power levels over a relatively wide range of output power levels. According to one or more examples, the configurable RF PA circuitry of the disclosure is to operate with relatively high efficiency at different output power levels based at least in part on intelligently selected configurations of different RF PAs using different voltage biasing sources and power control inputs. This disclosure is aimed to provide a detailed technical description of the RF PA circuitry, outlining unique features and functionality thereof, even advantages over existing solutions or technologies.

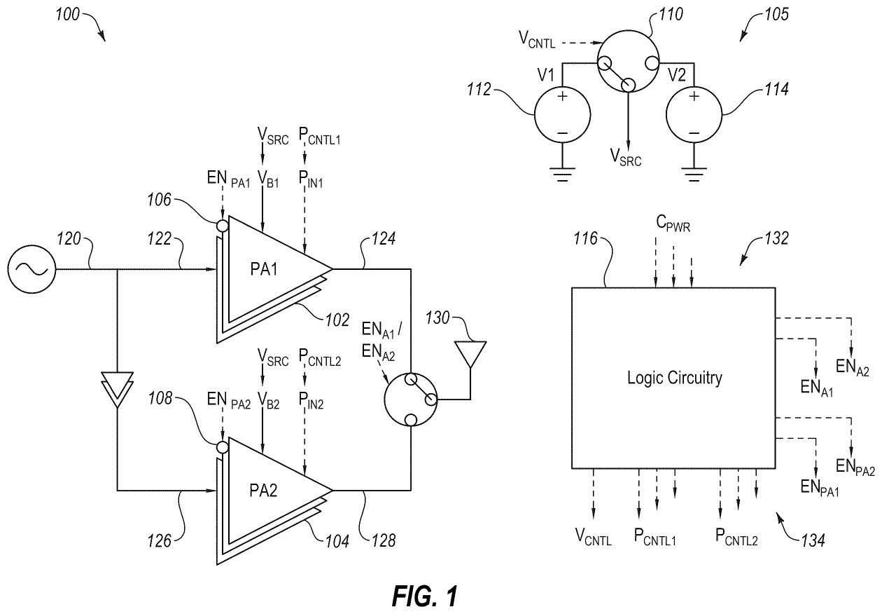

FIG. 1 is a schematic diagram of a configurable radio frequency (RF) power amplifier (PA) circuitry 100 (hereinafter, “RF PA circuitry 100”) for use in an RF transmitter, according to one or more examples.

In one or more examples of FIG. 1, RF PA circuitry 100 includes a first RF PA 102 (indicated as “PA1”), a second RF PA 104 (indicated as “PA2”), one or more enable switches 106 and 108 (hereinafter “enable switches 106 and 108”), one or more voltage source switches 110 (hereinafter “voltage source switch 110”), and a logic circuitry 116. First RF PA 102 includes a first amplifier input 122 coupled to an RF signal input 120. Second RF PA 104 includes a second amplifier input 126 also coupled to RF signal input 120. Second RF PA 104 is in parallel with first RF PA 102. In one or more examples, first RF PA 102 includes a first amplifier output 124 coupled to an antenna 130 (e.g., via one or more antenna switches), and second RF PA 104 includes a second amplifier output 128 coupled to antenna 130 (e.g., via the one or more antenna switches).

When first RF PA 102 is biased at a bias voltage, first RF PA 102 is adapted to amplify over a first RF PA output power range including a number of first RF PA output power levels. When second RF PA 104 is set at the same or similar bias voltage, second RF PA 104 is adapted to amplify over a second RF PA output power range including a number of second RF PA output power levels. In one or more examples, the second RF PA output power levels over the second RF PA output power range are greater than respective first RF PA output power levels over the first RF PA output power range. In one or more further examples, some of the second RF PA output power levels over the second RF PA output power range overlap with some of the first RF PA output power levels over the first RF PA output power range.

Enable switches 106 and 108 are for switchably enabling (e.g., turning or switching “on”) one of first RF PA 102 or second RF PA 104 for amplification. The enabled one of first RF PA 102 or second RF PA 104 may be voltage-biased using a voltage control circuitry 105. In FIG. 1, voltage control circuitry 105 includes voltage source switch 110, a first voltage source 112, and a second voltage source 114. First voltage source 112 is to provide a first voltage and second voltage source 114 is to provide a second voltage. In one or more examples, the second voltage is greater than the first voltage.

Voltage source switch 110 is for switchably coupling one of first voltage source 112 or second voltage source 114 to a switch output. The switch output of voltage source switch 110 is coupled to, via a voltage source line V_{SRC}, a voltage bias input V_{B1} of first RF PA 102 and a voltage bias input V_{B2} of second RF PA 104. In one or more examples, voltage source switch 110 is a single voltage source switch that is shared with first RF PA 102 and second RF PA 104. Voltage source switch 110 is for switchably coupling one of first voltage source 112 or second voltage source 114 to the voltage bias input V_{B1} or V_{B2} of an enabled one first RF PA 102 or second RF PA 104.

RF PA circuitry 100 is considered to be configurable, or even reconfigurable, according to one or more examples. Here, logic circuitry 116 is to receive (e.g., via inputs 132 thereof) control signals including a requested output power level (e.g., C_{PWR}) for RF PA circuitry 100. At least partially responsive to the control signals, logic circuitry 116 is to set (e.g., via outputs 134 thereof) enable switches 106 and 108, voltage source switch 110, and power control inputs P_{IN1}/P_{IN2} of the enabled one of first RF PA 102 or second RF PA 104 to amplify an RF transmit signal to (at least substantially) the requested output power level. In one or more examples, the amplified RF transmit signal may be provided at first amplifier output 124 or second amplifier output 128 of the enabled one of first RF PA 102 or second RF PA 104 for transmission via antenna 130.

In one or more specific examples, logic circuitry 116 is to use enable signals EN_{PA1} and EN_{PA2} provided at outputs 134 to enable one of first RF PA 102 or second RF PA 104. Logic circuitry 116 is also to use a voltage control signal V_{CNTL} provided at outputs 134 to set voltage source switch 110 to switchably couple one of first voltage source 112 or second voltage source 114 to the voltage source line V_{SRC}. This switching is performed at least to voltage bias, at voltage bias input V_{B1} or V_{B2}, the enabled one of first RF PA 102 or second RF PA 104. Logic circuitry 116 is also to use one of power control signals P_{CTL1} or P_{CTL2} provided at outputs 134 to set the power control inputs P_{IN1} or P_{IN2} of the enabled one of first RF PA 102 or second RF PA 104 to amplify the RF transmit signal to the requested output power level.

In one or more further examples, logic circuitry 116 may also use antenna switching signals EN_{A1} and/or EN_{A2} provided at outputs 134 to switchably couple antenna 130 to one of first amplifier output 124 of first RF PA 102 or second amplifier output 128 of second RF PA 104 for transmitting the amplified RF transmit signal.

Note that, as used herein, the actions of “setting” or “to set,” and “enabling” or “to enable,” for example, include not only the active changing of settings or states (e.g., from on to off, or from off to on, and so on) in response to control signals, but also include the maintaining of previous settings or states in response to the control signals when the previous settings or states need to be maintained (e.g., or kept the same).

According to one or more examples, logic circuitry 116 is to properly set the switches and the inputs to amplify the RF transmit signal to (at least substantially) the requested output power level for respective ones of different requested output power levels within different ranges of output power levels supported by RF PA circuitry 100. In one or more examples, the different ranges of output power levels supported by RF PA circuitry 100 are defined at least in part by respective combinations of one of first RF PA 102 or second RF PA 104 using one of first voltage source 112 or second voltage source 114.

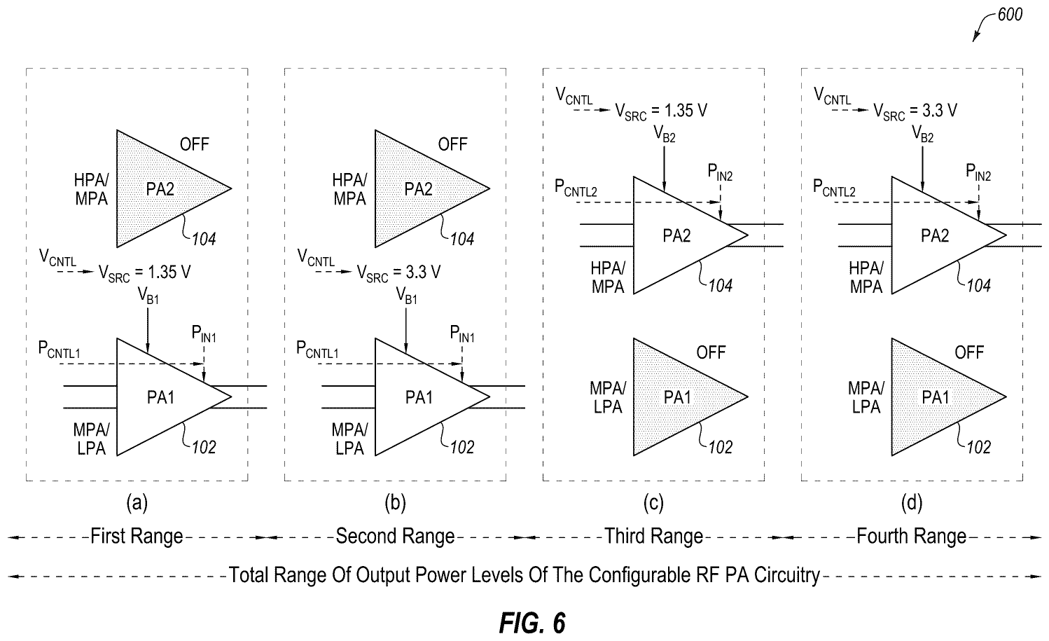

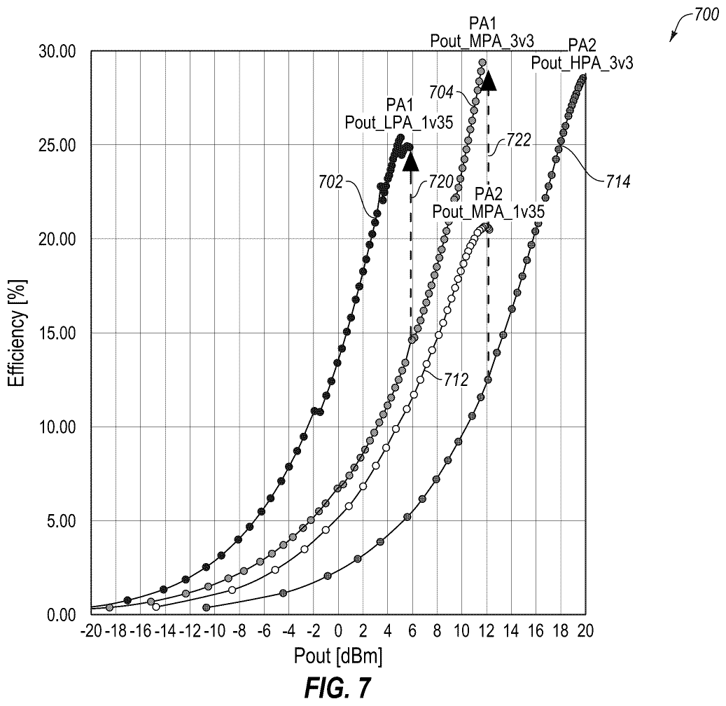

One or more examples of the different ranges of output power levels of RF PA circuitry 100 associated with these combinations are described later in relation to FIG. 6 and/or FIG. 7. According to one or more examples, first RF PA 102 is to amplify at a first output power (e.g., expressed in decibel-milliwatts or dBm) when biased at the first voltage and at a second output power when biased at the second voltage, where the second output power is greater than the first output power. In addition, second RF PA 104 is to amplify at a third output power when biased at the first voltage and at a fourth output power when biased at the second voltage, where the fourth output power is greater than the second output power and the third output power. In one or more examples, the third output power of second RF PA 104 is greater than the second output power of first RF PA 102. In one or more other examples, the third output power of second RF PA 104 is about the same as the second output power of first RF PA 102.

In FIG. 1, according to one or more examples, logic circuitry 116 comprises a look-up table (LUT). In one or more examples, the LUT is to provide, at least partially responsive to logic level input signals (‘0’ or ‘1’) at inputs 132 (e.g., the requested output power level or C_{PWR}), logic level output signals (‘0’ or ‘1’) at outputs 134 to amplify the RF transmit signal to (at least substantially) the requested output power level. In one or more examples, the LUT is to provide the logic level output signals at outputs 134 to set the enable switches 106 and 108, voltage source switch 110, and the power control inputs of first RF PA 102 or second RF PA 104 to amplify the RF transmit signal to (at least substantially) the requested output power level. In one or more other examples, the LUT is to provide the logic level output signals at outputs 134 to set voltage source switch 110 and the power control inputs of first RF PA 102 or second RF PA 104, where enable switches 106 and 108 are set by other control means.

In one or more examples, RF PA circuitry 100 is to operate with a pre-specified output impedance (e.g., about 50 ohms). Here, in one or more specific examples, the LUT is to set the power control inputs P_{IN1}/P_{IN2} (e.g., using power control signals P_{CTL1}/P_{CTL2}) to produce a bias current in the enabled one of first RF PA 102 or second RF PA 104 at least partially based on the pre-specified output impedance. The bias current is at least partially based on a ratio of the coupled one of the first voltage or the second voltage over the pre-specified output impedance.

In one or more examples, respective ones of first RF PA 102 and second RF PA 104 include a number of amplifier slices or slice circuits. Here, the power control inputs P_{IN1}/P_{IN2} of first RF PA 102 and second RF PA 104 enable or disable respective amplifier slices of the respective ones of first RF PA 102 and second RF PA 104 to produce the bias current for control over the output power level. For example, amplifier circuit slices may be selectively inserted into the circuit for increasing current and/or power or selectively removed from the circuit for decreasing the current and/or power.

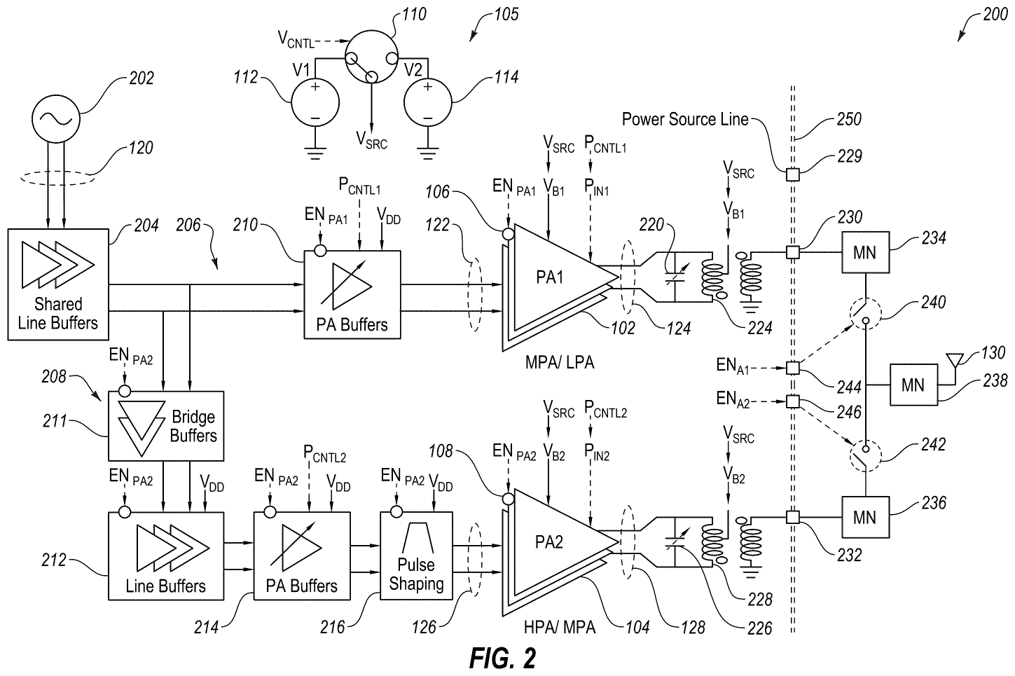

FIG. 2 is a schematic diagram of a configurable RF PA circuitry 200 (hereinafter, “RF PA circuitry 200”) for use in an RF transmitter, according to one or more further examples. In one or more examples, RF PA circuitry 200 of FIG. 2 includes at least some of the same circuits and/or components as RF PA circuitry 100 of FIG. 1, as indicated by like reference numerals between the figures, and may provide at least some of the same or similar operation as RF PA circuitry 100 of FIG. 1. In one or more examples, RF PA circuitry 200 may be part of an integrated circuit (IC).

An RF modulator 202 is to generate a modulated RF signal (e.g., provided at RF signal input 120) to be amplified and transmitted via antenna 130. Here, for example, a frequency synthesizer may generate a local oscillator (LO) signal based on a reference signal and, using a phase-locked loop (PLL), produce a high-frequency carrier signal that is a multiple of the reference frequency. RF modulator 202 may take digital data and embed it onto the high-frequency carrier signal to generate the modulated RF signal. In one or more examples, the RF signal has an RF frequency of about 2.45 Gigahertz (GHz), without limitation.

In one or more examples, an output of RF modulator 202 is coupled to an input of a shared line buffer circuitry 204. An output of shared line buffer circuitry 204 is coupled to an input of a first RF signal chain circuit portion 206 toward first RF PA 102. The output of shared line buffer circuitry 204 is also coupled to an input of a second RF signal chain circuit portion 208 toward second RF PA 104. At least in some contexts, the common RF signal input to the RF PA circuitry may be considered to be RF signal input 120, the output of shared line buffer circuitry 204, or other RF signal input, for example, when variations on the circuitry are used.

First RF signal chain circuit portion 206 is coupled between RF signal input 120 and first amplifier input 122 of first RF PA 102. In one or more examples, first RF signal chain circuit portion 206 includes a PA buffer circuitry 210 (e.g., a programmable/configurable PA driver). Second RF signal chain circuit portion 208 is coupled between RF signal input 120 and second amplifier input 126 of second RF PA 104. In one or more examples, second RF signal chain circuit portion 208 includes a bridge buffer circuitry 211, a line buffer circuitry 212, a PA buffer circuitry 214 (e.g., a programmable/configurable PA driver), and a pulse shaping circuitry 216, coupled in a series chain as depicted. Second RF signal chain circuit portion 208 including second RF PA 104 is in parallel with first RF signal chain circuit portion 206 including first RF PA 102.

In one or more examples, at least some circuits of first RF signal chain circuit portion 206 and second RF signal chain circuit portion 208 include respective enable switches (indicated as small circles in respective circuit blocks) for enabling or disabling the circuitry. For example, PA buffer circuitry 210 of first RF signal chain circuit portion 206 includes an enable switch controlled by the logic circuitry via the enable signal EN_{PA1}. In addition, bridge buffer circuitry 211, line buffer circuitry 212, PA buffer circuitry 214, and/or pulse shaping circuitry 216 of second RF signal chain circuit portion 208 include respective enable switches controlled by the logic circuitry via the enable signal EN_{PA2}. In one or more examples, any of the enable switches may be incorporated in or as part of the respective signal chain circuits, or alternatively, they may be separate and apart from the respective signal chain circuits. In one or more examples, the enable switches used to enable or disable first RF PA 102 or second RF PA 104 may be or include enable switches 106 and 108 and/or any one of the respective enable switches of first and second RF signal chain circuit portions 206 and 208 (e.g., first RF PA 102 or second RF PA 104 may be said to be enabled or disabled by additionally or alternatively enabling or disabling circuits in their respective signal chains).

Shared line buffer circuitry 204 is used to amplify the RF signal for propagation to PA buffer circuitry 210 (e.g., the PA driver) via differential RF transmission lines (e.g., a distance of about 1 millimeter may exist between the synthesizer/PLL and the RF PA, without limitation). When enabled, bridge buffer circuitry 211 is to propagate the RF signal for further amplification. When disabled, bridge drivers of bridge buffer circuitry 211 are in a high impedance mode. Line buffer circuitry 212 is used to amplify the RF signal for propagation to PA buffer circuitry 214 (e.g., the PA driver) via differential RF transmission lines. In one or more examples, pulse shaping circuitry 216 may be used to generate a lower duty cycle of the RF signal for output power control to achieve higher efficiency using second RF PA 104.

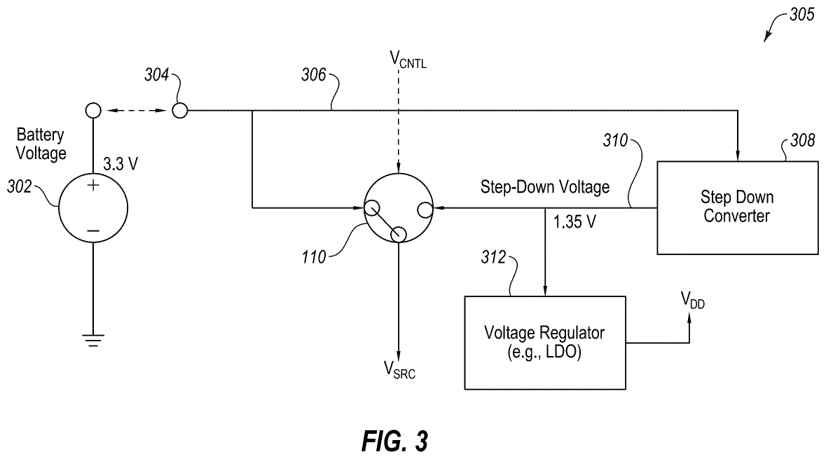

In one or more examples, voltage control circuitry 105 of FIG. 2 is implemented as a voltage control circuitry 305 of FIG. 3. In one or more examples, voltage control circuitry 305 may be or be part of a power management unit (PMU) associated with the IC. As depicted, voltage control circuitry 305 of FIG. 3 includes voltage source switch 110, a power source line 306, and a step-down converter 308. Power source line 306 is for coupling to a battery voltage source 302 (e.g., via one or more contacts or pins 304). Battery voltage source 302 has a battery voltage. Step-down converter 308 is coupled to power source line 306 which provides the battery voltage when battery voltage source 302 is connected. Step-down converter 308 is to convert the battery voltage to a step-down voltage, at a step-down voltage source line 310, to thereby provide a step-down voltage source. In one or more examples, step-down converter 308 is a DC-DC buck converter that employs a switching method (e.g., using inductor and transistor components) to achieve the voltage reduction. Accordingly, in one or more examples, first voltage source 112 of FIG. 1 or FIG. 2 is the step-down voltage source of FIG. 3, and second voltage source 114 of FIG. 1 or FIG. 2 is battery voltage source 302 of FIG. 3.

In a specific, non-limiting example, battery voltage source 302 is a relatively small battery voltage source, such as a lithium coin cell battery, used to power relatively small, low-power devices (including an IC). Here, battery voltage source 302 comprising the lithium coin cell battery has a battery voltage of about 3.3 volts, and the step-down voltage source has a step-down voltage of about 1.35 volts.

In one or more examples, a voltage regulator 312, such as a low dropout regulator (LDO), is coupled to step-down converter 308 via step-down voltage source line 310. Voltage regulator 312 is to regulate the step-down voltage to provide a regulated step-down voltage source having a regulated step-down voltage. In FIG. 3, the regulated step-down voltage is indicated as voltage V_{DD}.

With reference back to FIG. 2, first RF signal chain circuit portion 206 and second RF signal chain circuitry 208 are supplied or powered at the regulated step-down voltage of V_{DD}. For example, PA buffer circuitry 210 of first RF signal chain circuit portion 206 is supplied at V_{DD}, and bridge buffer circuitry 211, line buffer circuitry 212, PA buffer circuitry 214, and pulse shaping circuitry 216 of second RF signal chain circuitry 208 are supplied at V_{DD}. Note that the supply at V_{DD} for this circuitry is maintained irrespective of coupling position of voltage source switch 110.

In one or more examples, RF signal input 120 of RF PA circuitry 200 is an RF differential signal input that provides an RF differential signal. Accordingly, in one or more examples, first amplifier input 122 of first RF PA 102 is a first differential amplifier input and first amplifier output 124 of first RF PA 102 is a first differential amplifier output. In addition, second amplifier input 126 of second RF PA 104 is a second differential amplifier input and second amplifier output 128 of second RF PA 104 is a second differential amplifier output.

In one or more examples, RF PA circuitry 200 includes a first tunable capacitor circuitry 220 coupled to the first differential amplifier output of first RF PA 102. RF PA circuitry 200 further includes a second tunable capacitor circuitry 226 coupled to the second differential amplifier output of second RF PA 104. In one or more examples, first and second tunable capacitor circuitries 220 and 226 are tunable (variable and configurable) and provided to tune the tank to a center of the appropriate RF band of operation.

In one or more examples, RF PA circuitry 200 includes a first balun 224 coupled to the first differential amplifier output of first RF PA 102 (in parallel with first tunable capacitor circuitry 220 when used) for differential to single-ended transformation. RF PA circuitry 200 further includes a second balun 228 coupled to the second differential amplifier output of second RF PA 104 (in parallel with second tunable capacitor circuitry 226 when used) for differential to single-ended transformation. Respective ones of first balun 224 and second balun 228 may be referred to as transformers. In one or more examples, first balun 224 is adapted with a first turns ratio (e.g., 7:2, without limitation), second balun 228 is adapted with a second turns ratio (e.g., 4:2, without limitation), where the second turns ratio is different from the first turns ratio. In one or more examples, the respective turns ratios of the baluns may be determined based at least in part on impedance matching between the RF PA and the antenna and the different output powers provided at the different supply voltages.

In one or more examples, a voltage bias input V_{B1} of first balun 224 is at a center tap of first balun 224, and a voltage bias input V_{B2} of second balun 228 is at a center tap of second balun 228. In one or more examples, the switch output of voltage source switch 110 is coupled to voltage bias inputs V_{B1} and V_{B2} of first balun 224 and second balun 228, respectively, via voltage source line V_{SRC}. Thus, voltage source switch 110 is also used for switchably coupling one of first voltage source 112 or second voltage source 114 to the voltage bias input V_{B1} or V_{B2} of one of first balun 224 or second balun 228 of the enabled one of first RF PA 102 or second RF PA 104.

RF PA circuitry 200 is considered to be configurable, or even reconfigurable (e.g., changeable after initial circuit application, and/or changeable even “on-the-fly” in circuit operation), according to one or more examples. As discussed earlier, at least partially responsive to control signals, the logic circuitry (e.g., logic circuitry 116 of FIG. 1) is to set enable switches 106 and 108, voltage source switch 110, and power control inputs P_{IN1} or P_{IN2} to amplify an RF transmit signal to (at least substantially) the requested output power level. In one or more examples using RF PA circuitry 200 of FIG. 2, the logic circuitry is to set the enable switches 106 and 108 including those of first and second RF signal chain circuit portions 206 and 208 (e.g., via enable signals EN_{PA1} and/or EN_{PA2}), voltage source switch 110 for voltage biasing first RF PA 102 or second RF PA 104 as well as first balun 224 or second balun 228, and the power control inputs P_{IN1} or P_{IN2} of first RF PA 102 or second RF PA 104 to amplify the RF transmit signal to (at least substantially) the requested output power level. In one or more examples, the supply at V_{DD} for first and second RF signal chain circuit portions 206 and 208 is maintained irrespective of coupling position of voltage source switch 110.

In one or more further examples, at least some of the power control signals P_{CNTL1} or P_{CNTL2} are used to further control amplification in PA buffer circuitry 210 or PA buffer circuitry 214 of the enabled one of first RF PA 102 or second RF PA 104. In one or more further examples, first RF PA 102 or second RF PA 104 are controlled so as not to be enabled or switched on at the same time, and bridge buffer circuitries 211 are controlled so as to be enabled or switched on only when second RF PA 104 is enabled.

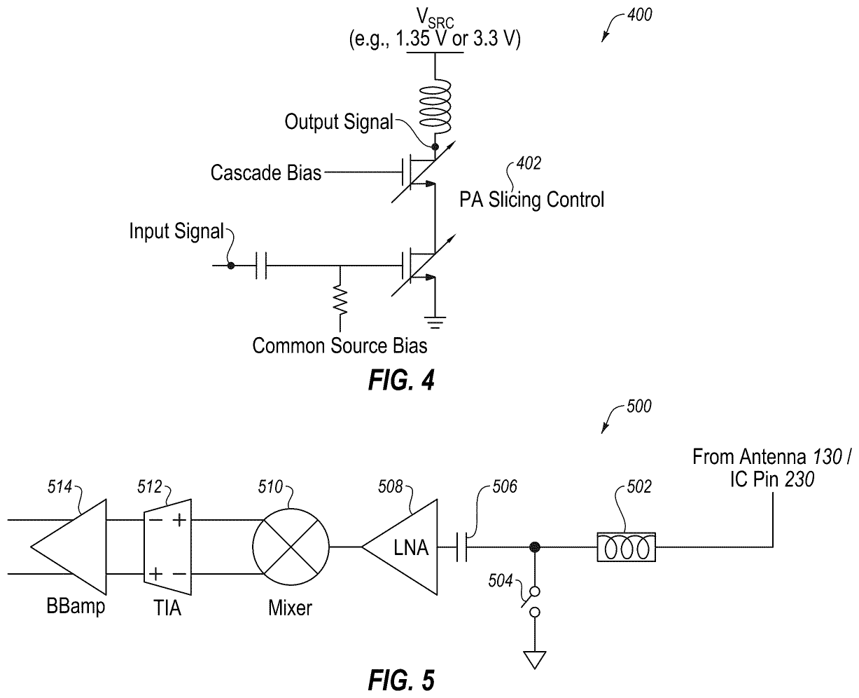

In one or more examples, respective ones of first RF PA 102 and second RF PA 104 are implemented as compressed class-B differential cascade circuits. In FIG. 4, one example of such a cascade circuit 400 is depicted in singled-end or half-circuit form. The full or differential circuit corresponding to the class-B differential cascade circuit includes an additional half-circuit mirrored next to the one depicted in FIG. 4, as one ordinarily skilled in the art would readily appreciate.

As represented in FIG. 4, cascade circuit 400 includes first and second transistors (e.g., bottom and top transistors, respectively) which are stacked vertically as shown. The bottom transistor may be referred to as a common source transistor, and the top transistor may be referred to as a cascode transistor. Cascade circuit 400 may be voltage-biased via an inductor at the top of the circuit (e.g., the voltage source line V_{SRC} may be coupled at the top, directly or indirectly). In one or more examples, the voltage biasing of cascade circuit 400 may be provided at the first voltage or the second voltage, with the voltage source line V_{SRC} being routed through the center tap of the balun for each RF PA (FIG. 2). An input signal (e.g., an RF transmit signal to be amplified) may be applied at the front of a capacitor coupled to a gate of the common source transistor, and an output signal may be taken from a drain of the cascode transistor.

As discussed earlier, each RF PA includes a number of amplifier slices, and the power control inputs of each one of the RF PAs are used to enable or disable respective amplifier slices to produce the appropriate bias current. In FIG. 4, a PA slicing control 402 of the RF PA indicates the slice variability of the cascode and common source transistors (indicated in the figure using respective variability arrows). In one or more examples, each one of the common source bias and the cascode bias may be varied and configurable (e.g., to optimize power and efficiency over corners, and so on).

Thus, with reference back to FIG. 2, voltage source switch 110 may be provided to commutate from about 1.35 volts to about 3.3 volts to translate the power from about 6 dBm to about 12 dBm (e.g., first RF PA 102) or from about 12 dBM to about 20 dBM (e.g., second RF PA 104). Note that the 3.3 volt supply is an unregulated supply, and as such, can drop down to about 1.8 volts. The 1.35 volt supply may be a regulated supply, coming from the step-down converter (e.g., the DC-DC buck converter), which may be supplied to the RF buffers and LO line buffers. In one or more examples, the voltage source switch and the voltage regulator (e.g., the LDO) are shared between first RF PA 102 and second RF PA 104 (e.g., to save area). The bridge buffers may be used to convey the RF signal from first RF PA 102 to second RF PA 104, while re-using the line buffers of first RF PA 102.

In one or more examples, RF PA circuitry 200 of FIG. 2 is part of an IC. In FIG. 2, an IC boundary of the IC having RF PA circuitry 200 is indicated by a dashed line 250 along which a number of IC pins of the IC are depicted. In one or more examples, the IC includes an IC input pin 229 for external coupling to first voltage source 112 (e.g., the battery voltage source). Internally, IC input pin 229 is coupled to the power source line (e.g., in FIG. 3, power source line 306 for coupling to battery voltage source 302).

In one or more examples, the IC including RF PA circuitry 200 is to operate with external circuitry outside of or external to the IC (e.g., depicted on the right of the IC boundary indicated by dashed line 250). In one or more examples, the IC includes at least a first IC output pin 230 and a second IC output pin 232. First IC output pin 230 is coupled to a first output of first balun 224 associated with first RF PA 102 (or, more generally, coupled to first amplifier output 124 of first RF PA 102). Second IC output pin 232 is coupled to a second output of second balun 228 associated with second RF PA 104 (or, more generally, coupled to second amplifier output 128 of second RF PA 104). In general, first IC output pin 230 and/or second IC output pin 232 are for external coupling to the external circuitry (e.g., including antenna 130) to provide the amplified RF transmit signal to the external circuitry for transmission.

In one or more examples, RF PA circuitry 200 is to operate with a pre-specified output impedance (e.g., about 50 ohms). Accordingly, the external circuitry may be adapted with a first impedance matching network 234 (indicated in the figure as a “matching network” (MN)) for coupling to first IC output pin 230, and/or a second impedance matching network 236 (also indicated in the figure as “MN”) for coupling to second IC output pin 232. In one or more examples, first impedance matching network 234 may be coupled to antenna 130 via a first antenna switch 240, and/or second impedance matching network 236 may be coupled to antenna 130 via a second antenna switch 242. In one or more other examples, the external circuitry may be further adapted with an impedance matching network 238 (indicated in the figure as “MN”) coupled to or with antenna 130.

In one or more examples, at least partially responsive to the control signals, the logic circuitry (e.g., logic circuitry 116 of FIG. 1) may use antenna switching signals EN_{A1} and/or EN_{A2} at third and/or fourth IC output pins 244 and 246, respectively, to switchably couple antenna 130 to first IC output pin 230 (e.g., to first amplifier output 124 of first RF PA 102) via first antenna switch 240 or to second IC output pin 232 (e.g., second amplifier output 128 of second RF PA 104) via second antenna switch 242.

In one or more example application scenarios, if an application provides that the requested output power level of RF PA circuitry 200 is to substantially vary over use of the IC including RF PA circuitry 200 (e.g., substantially vary over a relatively wide output power level range), then both external circuits at respective RF PA outputs should be arranged externally (e.g., external circuits at both the first RF PA output including first IC output pin 230, first impedance matching network 234, and/or first antenna switch 240, as well as the second RF PA output including second IC output pin 232, second impedance matching network 236, and/or second antenna switch 242). On the other hand, if an application provides that the requested output power level of RF PA circuitry 200 is to remain substantially fixed over use of the IC including RF PA circuitry 200 (e.g., substantially fixed over a relatively narrow output power level range), then an external circuit at only one RF PA output needs to be arranged externally (e.g., either an external circuit at the first RF PA output including first IC output pin 230, first impedance matching network 234, and/or first antenna switch 240, or at the second RF PA output including second IC output pin 232, second impedance matching network 236, and/or second antenna switch 242).

As described above in one or more examples, a suitable voltage and current for biasing a chosen RF PA are selected for efficient amplification responsive to a requested output power level. The configurable RF PA circuitry has the same, fixed load impedance, and therefore can transmit efficiently at multiple output powers. In one or more examples, the user of the IC is not required to make (e.g., any) hardware changes (e.g., on a PCB including the IC having the configurable RF PA circuitry) for respective output power levels. In existing RF PAs on the market, efficient transmission at multiple output powers is not possible since different output powers would result in different loads.

In one or more examples, RF PA circuitry 200 of FIG. 2 may be used in an RF transceiver which includes both an RF transmitter and an RF receiver. FIG. 5 is a schematic diagram of an RF receiver portion 500 of the RF transceiver, according to one or more examples. In FIG. 7, RF receiver portion 500 includes an inductor 502 having a first end coupled to the antenna at the output of the first RF PA (e.g., via first IC output pin 230) and a second end coupled to a receive/transmit (Rx/Tx) switch 504. The second end of inductor 502 is further coupled to an input of a low noise amplifier (LNA) 508 via a capacitor 506. An output of LNA 508 is coupled to an input of a mixer 510, which has an output coupled to an input of a transimpedance amplifier (TIA) 512. An output of TIA 512 is coupled to an input of a baseband amplifier (BBamp) 514. The logic circuitry may provide a switching signal to Rx/Tx switch 504 to enable receive (i.e., using RF receiver portion 500) or transmit for the RF transceiver. In one or more examples, the RF transceiver including the configurable RF PA circuitry of the disclosure comprises a BLUETOOTH® Low Energy (BLE) transceiver. BLUETOOTH® is a registered trademark of the Bluetooth Special Interest Group (SIG), Inc., of Kirkland, Washington, USA.

FIG. 6 is a diagram to illustrate multiple configurations 600 of a configurable RF PA circuitry, according to one or more examples. In one or more examples, multiple configurations 600 (hereinafter, “configurations”) may be provided at or by RF PA circuitry 100 of FIG. 1, RF PA circuitry 200 of FIG. 2, or variations thereof. In one or more examples, configurations 600 of the configurable RF PA circuitry are established or defined at least in part by respective combinations of first RF PA 102 or second RF PA 104 using one of the first power source or the second power source (e.g., first voltage source 112 and second voltage source 114 of FIGS. 1 and 2, or the battery voltage source 302 and the step-down voltage source of FIG. 3).

In general, when biased at a bias voltage, first RF PA 102 is adapted to amplify over a first RF PA output power range including a number of first RF PA output power levels. When biased at the same or similar bias voltage, second RF PA 104 is adapted to amplify over a second RF PA output power range including a number of second RF PA output power levels. In one or more examples, the second RF PA output power levels over the second RF PA output power range are greater than respective first RF PA output power levels over the first RF PA output power range. In one or more further examples, some of the second RF PA output power levels over the second RF PA output power range overlap with some of the first RF PA output power levels over the first RF PA output power range.

More specifically, first RF PA 102 is adapted to amplify over a first RF PA output power range (e.g., or generally at a first output power, as indicated in dBm) when biased at a first bias voltage (e.g., first voltage source 112 of FIG. 1 or 2) and over a second RF PA output power range (e.g., or generally at a second output power) when biased at a second bias voltage (e.g., second voltage source 114 of FIG. 1 or 2). Here, the first RF PA output power range of first RF PA 102 may be considered to provide low power amplification (LPA) and the second RF PA output power range of first RF PA 102 may be considered to provide medium power amplification (MPA). Thus, first RF PA 102 may be referred to as an “MPA/LPA” power amplifier. For example, the LPA may be about 6 dBm (or between about 5˜6 dBm) and the MPA may be about 12 dBm (or between about 10˜12 dBm). In one or more examples, respective adjustment level steps of about 1 dB may be provided in the first RF PA output power range and the second RF PA output power range.

Second RF PA 104 is adapted to amplify over a third RF PA output power range (e.g., or generally at a third output power) when biased at the first bias voltage (e.g., first voltage source 112 of FIG. 1 or 2) and over a fourth RF PA output power range (e.g., or generally at a fourth output power) when biased at the second bias voltage (e.g., second voltage source 114 of FIG. 1 or 2). Here, the third RF PA output power range of second RF PA 104 may be considered to provide medium power amplification (MPA) and the fourth RF PA output power range of second RF PA 104 may be considered to provide high power amplification (HPA). Thus, second RF PA 104 may be referred to as a “HPA/MPA” power amplifier. For example, the MPA may be about 12 dBm (or between about 10˜12 dBm) and the HPA may be about 20 dBm (or between about 18˜20 dBm). In one or more examples, respective adjustment level steps of about 1 dB may be provided in the third RF PA output power range and the fourth RF PA output power range.

As mentioned above, configurations 600 of the configurable RF PA circuitry may be established or defined at least in part by respective combinations of first RF PA 102 or second RF PA 104 using one of the first power source or the second power source. In one or more examples, the configurable RF PA circuitry may have at least four (4) configurations associated with at least four (4) ranges of output power levels. In one or more examples, the four (4) configurations associated with the four (4) ranges of output power levels may define the total range of output power levels of the configurable RF PA circuitry. In one or more examples, respective edges of adjacent ranges of output power levels may substantially align to provide a substantially continuous total range of output power levels (e.g., with substantially fixed sized adjustment steps even across configurations, from one configuration to another configuration) for the configurable RF PA circuitry.

To better illustrate, as depicted in a configuration (a) of FIG. 6, the configurable RF PA circuitry is to enable and bias first RF PA 102 at the first bias voltage (e.g., first voltage source 112 of FIG. 1 or 2) for amplification over a first range of output power levels (e.g., or generally at a first output power). Here, power control inputs PINI of first RF PA 102 may be used to control the power of first RF PA 102 (e.g., bias current control using amplifier slices of first RF PA 102).

As depicted in a configuration (b) of FIG. 6, the configurable RF PA circuitry is to enable and bias first RF PA 102 at the second bias voltage (e.g., second voltage source 114 of FIG. 1 or 2) for amplification over a second range of output power levels (e.g., or generally at a second output power). Here, power control inputs P_{IN1} of first RF PA 102 may again be used to control the power of first RF PA 102 (e.g., bias current control using amplifier slices of first RF PA 102).

As depicted in a configuration (c) of FIG. 6, the configurable RF PA circuitry is to enable and bias second RF PA 104 at the first bias voltage (e.g., first voltage source 112 of FIG. 1 or 2) for amplification over a third range of output power levels (e.g., or generally at a third output power). Here, power control inputs P_{IN2} of second RF PA 104 may be used to control the power of second RF PA 104 (e.g., bias current control using amplifier slices of second RF PA 104).

As depicted in a configuration (d) of FIG. 6, the configurable RF PA circuitry is to enable and bias second RF PA 104 at the second bias voltage (e.g., second voltage source 114 of FIG. 1 or 2) for amplification over a fourth range of output power levels (e.g., or generally at a fourth output power). Here, power control inputs P_{IN2} of second RF PA 104 may again be used to control the power of second RF PA 104 (e.g., bias current control using amplifier slices of second RF PA 104).

In one or more examples, (at least most of) the output power levels over the third range of output power levels (e.g., the third output power) of second RF PA 104 overlap with (at least most of) the output power levels over the second range of output power levels (e.g., the second output power) of first RF PA 102. Therefore, in one or more examples, the configurable RF PA circuitry may have four (4) configurations associated with (e.g., only) three (3) usable ranges of output power levels (as the second and the third ranges are substantially overlapping). For example, the three (3) usable ranges may correspond to configuration (a), configuration (b), and configuration (d) of FIG. 6, where configuration (c) is not used (see, e.g., FIG. 7). In one or more examples, the four (4) configurations associated with the three (3) usable ranges may define the total range of output power levels of the configurable RF PA circuitry. In one or more examples, respective edges of these adjacent ranges (e.g., the three (3) usable ranges) of output power levels may substantially align to provide a substantially continuous total range of output power levels (e.g., with substantially fixed sized adjustment steps even across configurations, from one configuration to another configuration) of the configurable RF PA circuitry.

In one or more examples, switching between respective ones of configurations 600 is performed so as to maintain a desired or targeted (e.g., minimum level of) efficiency of the configurable RF PA circuitry. In one or more examples, switching between respective ones of configurations 600 is performed to provide optimized efficiency of the configurable RF PA circuitry (e.g., using appropriate configuration switching points, as discussed later below).

In one or more examples, respective bias currents of first RF PA 102 and second RF PA 104 are determined (e.g., determined and configured in advance according to the LUT) at least partially based on the relation V=I*R, and more particularly, I=V/R, where I is the desired bias current, V is the bias voltage, and R is the resistance (i.e., the pre-specified output impedance, e.g., about 50 ohms). Put another way, the preconfigured settings for the amplifier bias current may be predetermined (e.g., determined and configured in advance according to the LUT) based on a ratio of the coupled one of the first voltage (e.g., about 1.35 volts) or the second voltage (e.g., about 3.3 volts) over the pre-specified output impedance (e.g., about 50 ohms).

FIG. 7 is a graph 700 of plots of simulation results indicating RF PA efficiency versus power output (dBm) over multiple configurations of a configurable RF PA circuitry, according to one or more examples. In one or more examples, the simulation results are associated with RF PA circuitry 100 of FIG. 1, RF PA circuitry 200 of FIG. 2, or variations thereof.

Graph 700 includes a plot 702 associated with the first RF PA when biased at the first voltage (e.g., about 1.35 volts), indicated as PA1: Pout_LPA_1v35 (e.g., a first configuration). Here, the configurable RF PA circuitry is to amplify at a first output power (e.g., in LPA mode, or about 6 dBm) associated with a first range of output power levels.

Graph 700 includes a plot 704 associated with the first RF PA when biased at the second voltage (e.g., about 3.3 volts), indicated as PAI: Pout_MPA_3v3 (e.g., a second configuration). Here, the configurable RF PA circuitry is to amplify at a second output power (e.g., in MPA mode, or about 12 dBm) associated with a second range of output power levels.

Graph 700 also includes a plot 712 associated with the second RF PA when biased at the first voltage (e.g., about 1.35 volts), indicated as PA2: Pout_MPA_1v35 (e.g., a third configuration). Here, the configurable RF PA circuitry is to amplify at a third output power (e.g., in MPA mode, or about 12 dBm) associated with a third range of output power levels.

Graph 700 also includes a plot 714 associated with the second RF PA when biased at the second voltage (e.g., about 3.3 volts), indicated as PA2: Pout_HPA_3v3 (e.g., a fourth configuration). Here, the configurable RF PA circuitry is to amplify at a fourth output power (e.g., in HPA mode, or about 20 dBm) associated with a fourth range of output power levels.

As is apparent, the third configuration (e.g., plot 712 associated with the MPA mode of the second RF PA) is substantially overlapping with the second configuration (e.g., plot 704 associated with the MPA mode of the first RF PA), in one or more examples. In one or more examples, the second configuration and/or the second range of output power levels associated with the first RF PA may be used (e.g., configurable) by the configurable RF PA circuitry for amplification, whereas the third configuration and/or the third range of output power levels associated with the second RF PA may not be used (e.g., not configurable) by the configurable RF PA circuitry for amplification. Other suitable variations to the configurations are realizable.

As discussed earlier above, the logic circuitry is used to switch amongst different configurations of the configurable RF PA circuitry. The selection of the configuration depends at least in part on the requested output power level. In one or more examples, the logic circuitry is adapted to perform switching amongst different RF PA configurations at least in part to maintain a desired or targeted (e.g., minimum level of) efficiency at a requested output power level. In one or more examples, efficiency is better facilitated by selecting a configuration “switching point(s)” at respective edges of adjacent ranges of output power levels, such that the desired minimum level of RF PA efficiency in one output power range aligns with the maximum (or otherwise high) level of RF PA efficiency in the other output power range. In one or more specific examples, the logic circuitry is adapted to perform switching amongst different RF PA configurations to maintain an optimized efficiency at a requested output power level.

In one or more examples of FIG. 7, a switching point 720 for switching between PA1: Pout_LPA_1v35 (e.g., the first configuration, or plot 702) and PAI: Pout_MPA_3v3 (e.g., the second configuration, or plot 704) is indicated at an output power level of about 6 dBm, with an efficiency of no less than about 15% being maintained. For example, at less than 6 dBm, the first configuration is selected; and at greater than 6 dBm, the second configuration is selected. In addition, a switching point 722 for switching between PAI: Pout_MPA_3v3 (e.g., the second configuration, or plot 704) and PA2: Pout_HPA_3v3 (e.g., the fourth configuration, or plot 714) is indicated at an output power level of about 12 dBm, with an efficiency of no less than about 12.5% being maintained. For example, at less than 12 dBm, the second configuration is selected; and at greater than 12 dBm, the fourth configuration is selected. Other configurations and switching points are realizable as one ordinarily skilled in the art will readily appreciate.

In existing conventional RF PAs, a single output power is targeted, and the drop in efficiency at back-off is simply accepted. In contrast, the configurable RF PA circuitry of the disclosure (e.g., as provided in a single IC package) may provide or even guarantee maximum efficiency at multiple different output powers (e.g., about 5 dBm/about 12 dBm/about 20 dBm). Efficiency is improved by adjusting both supply and current at various output power levels (e.g., a relatively wide range of output powers). The configurable RF PA circuitry of the disclosure may exhibit best in power class in terms of current consumption compared to existing products on the market. In one or more examples, the reconfigurable RF PA circuitry of the disclosure exhibits up to five (5) times current consumption reduction as compared to existing RF PAs on the market. Such a configurable RF PA circuitry eliminates the need for multiple products or PCB adjustments to support different power classes.

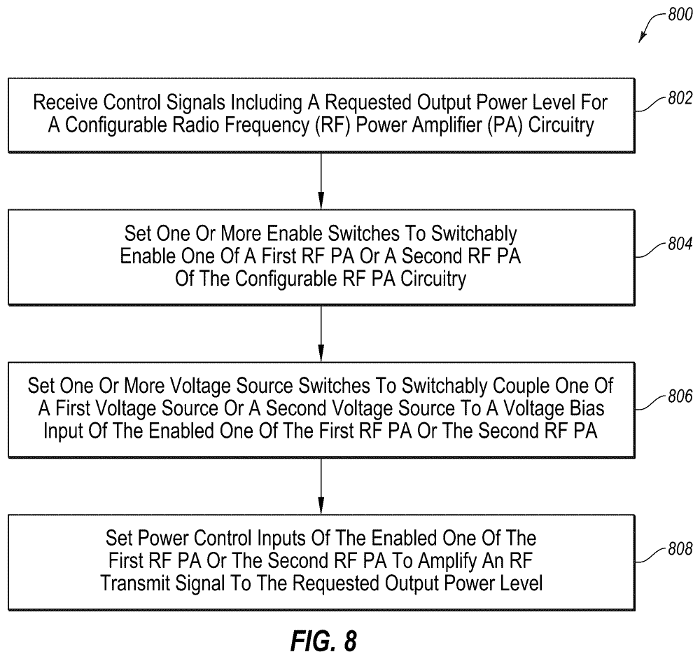

FIG. 8 is a flowchart of a method 800 of configuring a configurable RF PA circuitry to amplify according to a requested output power level, according to one or more examples. In one or more examples, method 800 may be performed at or by RF PA circuitry 100 of FIG. 1, RF PA circuitry 200 of FIG. 2, or variations thereof.

At an act 802 of method 800, control signals are received. The control signals include a requested output power level for a configurable RF PA circuitry. The configurable RF PA circuitry includes a first RF PA and a second RF PA. The first RF PA has a first amplifier input coupled to an RF signal input. The second RF PA has a second amplifier input coupled to the RF signal input. The second RF PA is in parallel with the first RF PA.

In one or more examples, the first RF PA is adapted to amplify over a first RF PA output power range (e.g., at a predetermined bias voltage) and the second RF PA is adapted to amplify over a second RF PA output power range (e.g., at the same or similar predetermined bias voltage). The second RF PA output power levels over the second RF PA output power range are greater than respective first RF PA output power levels over the first RF PA output power range. In one or more examples, some of the second RF PA output power levels over the second RF PA output power range overlap with some of the first RF PA output power levels over the first RF PA output power range.

In one or more specific examples, the first RF PA is adapted to amplify over a first RF PA output power range when biased at a first voltage and over a second RF PA output power range when biased at a second voltage, where the second RF PA output power range is greater than the first RF PA output power range. In addition, the second RF PA is adapted to amplify over a third RF PA output power range when biased at the first voltage and over a fourth RF PA output power range when biased at the second voltage, where the fourth RF PA output power range is greater than the second and the third RF PA output power ranges.

At least partially responsive to the control signals including the requested output power level, the following acts may be performed. At an act 804 of method 800, one or more enable switches (hereinafter “enable switches”) are set to switchably enable one of the first RF PA or the second RF PA. At an act 806 of method 800, one or more voltage source switches (hereinafter “voltage source switch”) are set to switchably couple one of a first voltage source (e.g., having a first voltage) or a second voltage source (e.g., having a second voltage) to a voltage bias input of the enabled one of the first RF PA or the second RF PA. At an act 808 of method 800, power control inputs of the enabled one of the first RF PA or the second RF PA are set to amplify an RF transmit signal to (at least substantially) the requested output power level.

In one or more examples of method 800, the control signals comprise input logic level signals received at a look-up table (LUT). Here, at the act 808, setting the power control inputs comprises setting output logic level signals of the LUT to set the power control inputs to produce a bias current in the enabled one of the first RF PA or the second RF PA. The bias current is at least partially determined based on a ratio of the coupled one of the first voltage or the second voltage over a pre-specified output impedance of the configurable RF PA circuitry. In one or more examples, respective ones of the first RF PA and the second RF PA include a number of amplifier slices, and the power control inputs of the respective ones of the first RF PA and the second RF PA are to enable or disable respective amplifier slices of the respective ones of the first RF PA and the second RF PA to produce the bias current.

In one or more examples of method 800, the method comprises an additional act of converting a battery voltage from a battery voltage source to a step-down voltage to provide a step-down voltage source. In one or more examples, the first voltage source is the step-down voltage source where the first voltage is the step-down voltage, and the second voltage source is the battery voltage source where the second voltage is the battery voltage.

In one or more examples of method 800, the configurable RF PA circuitry includes a first RF signal chain circuit portion and a second RF signal chain circuit portion. The first RF signal chain circuit portion is coupled between the RF signal input and the first amplifier input of the first RF PA. The second RF signal chain circuit portion is coupled between the RF signal input and the second amplifier input of the second RF PA. Here, method 800 comprises the additional acts of regulating the step-down voltage to produce a regulated step-down voltage source, and supplying power to the first RF signal chain circuitry and the second RF signal chain circuitry via the regulated step-down voltage irrespective of coupling position of the voltage source switch.

In one or more examples of method 800, the acts 804, 806, and 808 include the following additional acts. In the one or more examples, the configurable RF PA circuitry is to amplify over at least a first range of output power levels and a second range of output power levels, where the output power levels over the second range are greater than respective output power levels over the first range. At least partially responsive to the control signals including the requested output power level to be a first requested output power level within the first range of output power levels: the enable switches are set to enable the first RF PA and disable the second RF PA, the voltage source switch is set to switchably couple the first voltage source to the voltage bias input of the first RF PA, and the power control inputs of the first RF PA are set to amplify the RF transmit signal to (at least substantially) the first requested output power level. At least partially responsive to the control signals including the requested output power level to be a second requested output power level within the second range of output power levels: the enable switches are set to enable the first RF PA and disable the second RF PA, the voltage source switch is set to switchably couple the second voltage source to the voltage bias input of the first RF PA, and the power control inputs of the first RF PA are set to amplify the RF transmit signal to (at least substantially) the second requested output power level.

In one or more examples of method 800, the acts 804, 806, and 808 include the following further acts. In the one or more examples, the configurable RF PA circuitry is to amplify over at least a third range of output power levels, where the output power levels over the third range are greater than respective output power levels over the second range. At least partially responsive to the control signals including the requested output power level to be a third requested output power level within the third range of output power levels: the enable switches are set to enable the second RF PA and disable the first RF PA, the voltage source switch is set to switchably couple the second voltage source to a voltage bias input of the second RF PA, and power control inputs of the second RF PA are set to amplify the RF transmit signal to (at least substantially) the third requested output power level.

In one or more examples of method 800, the acts 804, 806, and 808 include the following even further acts. In the one or more examples, the configurable RF PA circuitry is to amplify further over at least a fourth range of output power levels, where the output power levels over the fourth range are greater than respective output power levels over the third range. At least partially responsive to the control signals including the requested output power level to be a third requested output power level within the third range of output power levels: the enable switches are set to enable the second RF PA and disable the first RF PA, the voltage source switch is set to switchably couple the first voltage source to the voltage bias input of the second RF PA, and the power control inputs of the second RF PA are set to amplify the RF transmit signal to (at least substantially) the third requested output power level. At least partially responsive to the control signals including the requested output power level to be a fourth requested output power level within the fourth range of output power levels: the enable switches are set to enable the second RF PA and disable the first RF PA, the voltage source switch is set to switchably couple the second voltage source to the voltage bias input of the second RF PA, and the power control inputs of the second RF PA are set to amplify the RF transmit signal to (at least substantially) the fourth requested output power level.

In one or more examples of method 800, the first amplifier input of the first RF PA comprises a first differential amplifier input and the second amplifier input of the second RF PA comprises a second differential amplifier input. In addition, the configurable RF PA circuitry further includes a first balun coupled to a first differential amplifier output of the first RF PA and a second balun coupled to a second differential amplifier output of the second RF PA. In one or more examples, setting the voltage source switch in act 806 is also for switchably coupling one of the first voltage source or the second voltage source to a voltage bias input of one of the first balun or the second balun of the enabled one of the first RF PA or the second RF PA.

Accordingly, in one or more examples, the configurable RF PA circuitry of the disclosure may improve upon battery life of a device, as efficient transmission results in lower current consumption and therefore longer battery life. In one or more examples, the configurable RF PA circuitry of the disclosure may also reduce development costs, as there is no need to develop multiple RF PA IC products for different power classes.

As used herein, the term “substantially” in reference to a given parameter, property, or condition means and includes to a degree that one skilled in the art would understand that the given parameter, property, or condition is met with a small degree of variance, such as within acceptable manufacturing tolerances. For example, a parameter that is substantially met may be at least about 90% met, at least about 95% met, or even at least about 99% met. The term “about” may be understood by one skilled in the art in the same way.

As used in the present disclosure, the terms “module” or “component” may refer to specific hardware implementations may perform the actions of the module or component or software objects or software routines that may be stored on or executed by general purpose hardware (e.g., computer-readable media, processing devices, without limitation) of the computing system. In one or more examples, the different components, modules, engines, and services described in the present disclosure may be implemented as objects or processes that execute on the computing system (e.g., as separate threads, without limitation). While some of the system and methods described in the present disclosure are generally described as being implemented in software (stored on or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.,” or “one or more of A, B, and C, etc.,” is used, in general such a construction is intended to include A alone, B alone, C alone, A and B together, A and C together, B and C together, or A, B, and C together, etc.

Any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

A non-exhaustive, non-limiting list of examples follows. Note that each of the examples listed below is explicitly and individually indicated as being combinable with all others of the examples listed below and examples discussed above. It is intended, however, that these examples are combinable with all other examples unless it would be apparent to one of ordinary skill in the art that the examples are not combinable.

Embodiment 1: An apparatus comprising: a configurable radio frequency (RF) power amplifier (PA) circuitry including: a first RF PA, the first RF PA including a first amplifier input coupled to an RF signal input; a second RF PA, the second RF PA including a second amplifier input coupled to the RF signal input, the second RF PA in parallel with the first RF PA; one or more enable switches, the one or more enable switches for switchably enabling one of the first RF PA or the second RF PA; one or more voltage source switches, the one or more voltage source switches for switchably coupling one of a first voltage source or a second voltage source to a voltage bias input of an enabled one the first RF PA or the second RF PA, the first voltage source having a first voltage, the second voltage source having a second voltage greater than the first voltage; and a logic circuitry, the logic circuitry to receive control signals including a requested output power level for the configurable RF PA circuitry, the logic circuitry to set the one or more enable switches, the one or more voltage source switches, and power control inputs of the enabled one of the first RF PA or the second RF PA to amplify an RF transmit signal to at least substantially the requested output power level.

Embodiment 2: The apparatus according to Example 1, wherein: the first RF PA is to amplify over a first RF PA output power range when biased at the first voltage and over a second RF PA output power range when biased at the second voltage, the second RF PA output power range greater than the first RF PA output power range, the second RF PA is to amplify over a third RF PA output power range when biased at the first voltage and over a fourth RF PA output power range when biased at the second voltage, the fourth RF PA output power range greater than the second and the third RF PA output power ranges.

Embodiment 3: The apparatus according to any of Examples 1 and 2, wherein the configurable RF PA circuitry is to operate with a pre-specified output impedance, and wherein: the logic circuitry is to set the one or more enable switches, the one or more voltage source switches, and the power control inputs to amplify the RF transmit signal to at least substantially the requested output power level for respective ones of different requested output power levels within different ranges of output power levels of the configurable RF PA circuitry based on the pre-specified output impedance, the different ranges of output power levels of the configurable RF PA circuitry defined at least in part by respective combinations of one of the first RF PA or the second RF PA using one of the first voltage source or the second voltage source.

Embodiment 4: The apparatus according to any of Examples 1 through 3, wherein the configurable RF PA circuitry is to operate with a pre-specified output impedance, and wherein: the logic circuitry comprises a look-up table (LUT), and the LUT is to provide output logic level signals to set the power control inputs to produce a bias current in the enabled one of the first RF PA or the second RF PA at least partially responsive to the control signals comprising input logic level signals, the bias current at least partially based on a ratio of the coupled one of the first voltage or the second voltage over the pre-specified output impedance.

Embodiment 5: The apparatus according to any of Examples 1 through 4, wherein: respective ones of the first RF PA and the second RF PA include a number of amplifier slices, the power control inputs of the respective ones of the first RF PA and the second RF PA to enable or disable respective amplifier slices of the respective ones of the first RF PA and the second RF PA to produce the bias current.

Embodiment 6: The apparatus according to any of Examples 1 through 5, wherein: when the logic circuitry is to receive control signals including the requested output power level comprising a first requested output power level within a first range of output power levels of the configurable RF PA circuitry, the logic circuitry is to: set the one or more enable switches to switchably enable the first RF PA; set the one or more voltage source switches to switchably couple the first voltage source to the voltage bias input of the first RF PA; and set the power control inputs of the first RF PA to amplify the RF transmit signal to at least substantially the first requested output power level; and when the logic circuitry is to receive control signals including the requested output power level comprising a second requested output power level within a second range of output power levels of the configurable RF PA circuitry, the logic circuitry is to: set the one or more enable switches to switchably enable the first RF PA; set the one or more voltage source switches to switchably couple the second voltage source to the voltage bias input of the first RF PA; and set the power control inputs of the first RF PA to amplify the RF transmit signal to at least substantially the second requested output power level.

Embodiment 7: The apparatus according to any of Examples 1 through 6, wherein: when the logic circuitry is to receive control signals including the requested output power level comprising a third requested output power level within a third range of output power levels of the configurable RF PA circuitry, the logic circuitry is to: set the one or more enable switches to switchably enable the second RF PA; set the one or more voltage source switches to switchably couple the second voltage source to the voltage bias input of the second RF PA; and set the power control inputs of the second RF PA to amplify the RF transmit signal to at least substantially a fourth requested output power level.

Embodiment 8: The apparatus according to any of Examples 1 through 7, wherein: when the logic circuitry is to receive control signals including the requested output power level comprising a third requested output power level within a third range of output power levels of the configurable RF PA circuitry, the logic circuitry is to: set the one or more enable switches to switchably enable the second RF PA; set the one or more voltage source switches to switchably couple the first voltage source to the voltage bias input of the second RF PA; and set the power control inputs of the second RF PA to amplify the RF transmit signal to at least substantially the third requested output power level; and when the logic circuitry is to receive control signals including the requested output power level comprising a fourth requested output power level within a fourth range of output power levels of the configurable RF PA circuitry, the logic circuitry is to: set the one or more enable switches to switchably enable the second RF PA; set the one or more voltage source switches to switchably couple the second voltage source to the voltage bias input of the second RF PA; and set the power control inputs of the second RF PA to amplify the RF transmit signal to at least substantially the fourth requested output power level.

Embodiment 9: The apparatus according to any of Examples 1 through 8, comprising: a power source line, the power source line for coupling to a battery voltage source having a battery voltage, the second voltage source comprising the battery voltage source and the second voltage comprising the battery voltage; and a step-down converter, the step-down converter coupled to the power source line, the step-down converter to convert the battery voltage to a step-down voltage to provide a step-down voltage source, the first voltage source comprising the step-down voltage source and the first voltage comprising the step-down voltage.

Embodiment 10: The apparatus according to any of Examples 1 through 9, comprising: a voltage regulator, the voltage regulator coupled to the step-down converter, the voltage regulator to regulate the step-down voltage to provide a regulated step-down voltage source having a regulated step-down voltage.

Embodiment 11: The apparatus according to any of Examples 1 through 10, wherein: the configurable RF PA circuitry includes: a first RF signal chain circuit portion, the first RF signal chain circuit portion coupled between the RF signal input and the first amplifier input of the first RF PA, the first RF signal chain circuit portion supplied at the regulated step-down voltage irrespective of coupling position of the one or more voltage source switches; and a second RF signal chain circuitry, the second RF signal chain circuit portion coupled between the RF signal input and the second amplifier input of the second RF PA, the second RF signal chain circuit portion supplied at the regulated step-down voltage irrespective of coupling position of the one or more voltage source switches.

Embodiment 12: The apparatus according to any of Examples 1 through 11, wherein the first amplifier input comprises a first differential amplifier input and the second amplifier input comprises a second differential amplifier input, and wherein: the configurable RF PA circuitry includes: a first balun coupled to a first differential amplifier output of the first RF PA; and a second balun coupled to a second differential amplifier output of the second RF PA, wherein the one or more voltage source switches is for switchably coupling the one of the first voltage source or the second voltage source to a voltage bias input of one of the first balun or the second balun of the enabled one the first RF PA or the second RF PA.

Embodiment 13: The apparatus according to any of Examples 1 through 12, comprising: an integrated circuit (IC) including the configurable RF PA circuitry, the IC including: a first IC output pin, the first IC output pin coupled to a first output of the first balun; and a second IC output pin, the second IC output pin coupled to a second output of the second balun.

Embodiment 14: A method comprising: receiving control signals including a requested output power level for a configurable radio frequency (RF) power amplifier (PA) circuitry, the configurable RF PA circuitry including a first RF PA and a second RF PA, the first RF PA having a first amplifier input coupled to an RF signal input, the second RF PA having a second amplifier input coupled to the RF signal input, the second RF PA in parallel with the first RF PA; and at least partially responsive to the control signals: setting one or more enable switches to switchably enable one of the first RF PA or the second RF PA; setting one or more voltage source switches to switchably couple one of a first voltage source or a second voltage source to a voltage bias input of the enabled one of the first RF PA or the second RF PA, the first voltage source having a first voltage, the second voltage source having a second voltage greater than the first voltage; and setting power control inputs of the enabled one of the first RF PA or the second RF PA to amplify an RF transmit signal to at least substantially the requested output power level.

Embodiment 15: The method according to Example 14, wherein the configurable RF PA circuitry is to operate with a pre-specified output impedance, the control signals comprise input logic level signals received at a look-up table (LUT), and setting the power control inputs comprises: setting output logic level signals of the LUT to set the power control inputs to produce a bias current in the enabled one of the first RF PA or the second RF PA at least partially responsive to the control signals, the bias current at least partially based on a ratio of the coupled one of the first voltage or the second voltage over the pre-specified output impedance.

Embodiment 16: The method according to any of Examples 14 and 15, comprising: converting a battery voltage from a battery voltage source to a step-down voltage to provide a step-down voltage source, the first voltage source comprising the step-down voltage source and the first voltage comprising the step-down voltage, the second voltage source comprising the battery voltage source and the second voltage comprising the battery voltage.

Embodiment 17: The method according to any of Examples 14 through 16, wherein the configurable RF PA circuitry includes a first RF signal chain circuit portion and a second RF signal chain circuit portion, the first RF signal chain circuit portion coupled between the RF signal input and the first amplifier input of the first RF PA, the second RF signal chain circuit portion coupled between the RF signal input and the second amplifier input of the second RF PA, the method comprising: regulating the step-down voltage to produce a regulated step-down voltage source; and supplying power to the first RF signal chain circuitry and the second RF signal chain circuitry via the regulated step-down voltage irrespective of coupling position of the one or more voltage source switches.

Embodiment 18: The method according to any of Examples 14 through 17, comprising: at least partially responsive to the control signals including the requested output power level to be a first requested output power level within a first range of output power levels of the configurable RF PA circuitry: setting the one or more enable switches to enable the first RF PA and disable the second RF PA; setting the one or more voltage source switches to switchably couple the first voltage source to the voltage bias input of the first RF PA; setting the power control inputs of the first RF PA to amplify the RF transmit signal to at least substantially the first requested output power level; and at least partially responsive to the control signals including the requested output power level to be a second requested output power level within a second range of output power levels of the configurable RF PA circuitry: setting the one or more enable switches to enable the first RF PA and disable the second RF PA; setting the one or more voltage source switches to switchably couple the second voltage source to the voltage bias input of the first RF PA; and setting the power control inputs of the first RF PA to amplify the RF transmit signal to at least substantially the second requested output power level.

Embodiment 19: The method according to any of Examples 14 through 18, comprising: at least partially responsive to the control signals including the requested output power level to be a third requested output power level within a third range of output power levels of the configurable RF PA circuitry: setting the one or more enable switches to enable the second RF PA and disable the first RF PA; setting the one or more voltage source switches to switchably couple the second voltage source to a voltage bias input of the second RF PA; and setting power control inputs of the second RF PA to amplify the RF transmit signal to at least substantially the third requested output power level.

Embodiment 20: The method according to any of Examples 14 through 19, comprising: at least partially responsive to the control signals including the requested output power level to be a third requested output power level within a third range of output power levels of the configurable RF PA circuitry: setting the one or more enable switches to enable the second RF PA and disable the first RF PA; setting the one or more voltage source switches to switchably couple the first voltage source to a voltage bias input of the second RF PA; and setting power control inputs of the second RF PA to amplify the RF transmit signal to at least substantially the third requested output power level; and at least partially responsive to the control signals including the requested output power level to be a fourth requested output power level within a fourth range of output power levels of the configurable RF PA circuitry: setting the one or more enable switches to enable the second RF PA and disable the first RF PA; setting the one or more voltage source switches to switchably couple the second voltage source to the voltage bias input of the second RF PA; and setting the power control inputs of the second RF PA to amplify the RF transmit signal to at least substantially the fourth requested output power level.

Embodiment 21: The method according to any of Examples 14 through 20, wherein the first amplifier input comprises a first differential amplifier input, the second amplifier input comprises a second differential amplifier input, the configurable RF PA circuitry includes a first balun coupled to a first differential amplifier output of the first RF PA, the configurable RF PA circuitry includes a second balun coupled to a second differential amplifier output of the second RF PA, and wherein setting the one or more voltage source switches is for switchably coupling one of the first voltage source or the second voltage source to a voltage bias input of one of the first balun or the second balun of the enabled one of the first RF PA or the second RF PA.

Embodiment 22: An apparatus comprising: an integrated circuit (IC) comprising: a step-down converter, the step-down converter coupled to a power source line, the power source line for coupling to a battery voltage source having a battery voltage, the step-down converter to convert the battery voltage to a step-down voltage to provide a step-down voltage source; a configurable radio frequency (RF) power amplifier (PA) circuitry, the configurable RF PA circuitry including: a first RF PA, the first RF PA including a first amplifier input coupled to an RF signal input, the first RF PA adapted to amplify over a first RF PA output power range when voltage biased at the step-down voltage and over a second RF PA output power range when voltage biased at the battery voltage, the second RF PA output power range greater than the first RF PA output power range; a second RF PA, the second RF PA including a second amplifier input coupled to the RF signal input, the second RF PA in parallel with the first RF PA, the second RF PA adapted to amplify over a third RF PA output power range when voltage biased at the step-down voltage and over a fourth RF PA output power range when voltage biased at the battery voltage, the fourth RF PA output power range greater than the second RF PA output power range and the third RF PA output power range; one or more enable switches, the one or more enable switches for switchably enabling one of the first RF PA or the second RF PA to amplify an RF transmit signal; and ones or more voltage source switches, the one or more voltage source switches for switchably coupling one of the step-down voltage source or the battery voltage source to a voltage bias input of the enabled one the first RF PA or the second RF PA.

Embodiment 23: The apparatus according to Example 22, wherein the IC comprising the configurable RF PA circuitry includes: a logic circuitry, the logic circuitry to receive control signals including a requested output power level for the configurable RF PA circuitry, the logic circuitry to set the one or more enable switches, the one or more voltage source switches, and power control inputs of the enabled one of the first RF PA or the second RF PA to amplify the RF transmit signal to at least substantially the requested output power level.

Embodiment 24: The apparatus according to any of Examples 22 and 23, wherein the configurable RF PA circuitry is to operate with a pre-specified output impedance, and wherein: the logic circuitry comprises a look-up table (LUT), the LUT to provide output logic level signals to set the power control inputs to produce a bias current in the enabled one of the first RF PA or the second RF PA at least partially responsive to the control signals comprising input logic level signals, the bias current at least partially based on a ratio of the coupled one of the step-down voltage or the battery voltage over the pre-specified output impedance, and respective ones of the first RF PA and the second RF PA include a number of amplifier slices, and the power control inputs of the respective ones of the first RF PA and the second RF PA are to enable or disable respective amplifier slices of the respective ones of the first RF PA and the second RF PA to produce the bias current.

Embodiment 25: The apparatus according to any of Examples 22 through 24, wherein the first amplifier input comprises a first differential amplifier input, the second amplifier input comprises a second differential amplifier input, and the IC comprising the configurable RF PA circuitry includes: a first balun coupled to a first differential amplifier output of the first RF PA; a second balun coupled to a second differential amplifier output of the second RF PA; a first IC output pin, the first IC output pin coupled to a first output of the first balun; and a second IC output pin, the second IC output pin coupled to a second output of the second balun, wherein the one or more voltage source switches is for switchably coupling the one of the first voltage source or the second voltage source to a voltage bias input of one of the first balun or the second balun of the enabled one the first RF PA or the second RF PA.

Embodiment 26: The apparatus according to any of Examples 22 through 25, wherein the IC comprising the configurable RF PA circuitry includes: a third IC output pin, the third IC output pin to provide a control signal to switchably control an antenna switch for switchably coupling an antenna to one of the first IC output pin through a first impedance matching network or the second IC output pin through a second impedance matching network.

Embodiment 27: The apparatus according to any of Examples 22 through 26, wherein the IC comprising the configurable RF PA circuitry includes: a voltage regulator, the voltage regulator coupled to the step-down converter, the voltage regulator to regulate the step-down voltage to provide a regulated step-down voltage source; a first RF signal chain circuit portion, the first RF signal chain circuit portion coupled between the RF signal input and the first amplifier input of the first RF PA, the first RF signal chain circuit portion supplied at the regulated step-down voltage irrespective of coupling position of the one or more voltage source switches; and a second RF signal chain circuit portion, the second RF signal chain circuit portion coupled between the RF signal input and the second amplifier input of the second RF PA, the second RF signal chain circuit portion supplied at the regulated step-down voltage irrespective of coupling position of the one or more voltage source switches, wherein respective ones of the first RF signal chain circuit portion and the second RF signal chain circuit portion include one or more of a line buffer circuitry, a PA buffer circuitry, or a pulse shaping circuitry.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. An apparatus comprising:
a configurable radio frequency (RF) power amplifier (PA) circuitry including:
a first RF PA, the first RF PA including a first amplifier input coupled to an RF signal input;
a second RF PA, the second RF PA including a second amplifier input coupled to the RF signal input, the second RF PA in parallel with the first RF PA;
one or more enable switches, the one or more enable switches for switchably enabling one of the first RF PA or the second RF PA;
one or more voltage source switches, the one or more voltage source switches for switchably coupling one of a first voltage source or a second voltage source to a voltage bias input of an enabled one the first RF PA or the second RF PA, the first voltage source having a first voltage, the second voltage source having a second voltage greater than the first voltage; and
a logic circuitry, the logic circuitry to receive control signals including a requested output power level for the configurable RF PA circuitry, the logic circuitry to set the one or more enable switches, the one or more voltage source switches, and power control inputs of the enabled one of the first RF PA or the second RF PA to amplify an RF transmit signal to at least substantially the requested output power level.

2. The apparatus of claim 1, wherein:
the first RF PA is to amplify over a first RF PA output power range when biased at the first voltage and over a second RF PA output power range when biased at the second voltage, the second RF PA output power range greater than the first RF PA output power range,
the second RF PA is to amplify over a third RF PA output power range when biased at the first voltage and over a fourth RF PA output power range when biased at the second voltage, the fourth RF PA output power range greater than the second and the third RF PA output power ranges.

3. The apparatus of claim 2, wherein the configurable RF PA circuitry is to operate with a pre-specified output impedance, and wherein:
the logic circuitry is to set the one or more enable switches, the one or more voltage source switches, and the power control inputs to amplify the RF transmit signal to at least substantially the requested output power level for respective ones of different requested output power levels within different ranges of output power levels of the configurable RF PA circuitry based on the pre-specified output impedance, the different ranges of output power levels of the configurable RF PA circuitry defined at least in part by respective combinations of one of the first RF PA or the second RF PA using one of the first voltage source or the second voltage source.

4. The apparatus of claim 1, wherein the configurable RF PA circuitry is to operate with a pre-specified output impedance, and wherein:
the logic circuitry comprises a look-up table (LUT), and
the LUT is to provide output logic level signals to set the power control inputs to produce a bias current in the enabled one of the first RF PA or the second RF PA at least partially responsive to the control signals comprising input logic level signals, the bias current at least partially based on a ratio of the coupled one of the first voltage or the second voltage over the pre-specified output impedance.

5. The apparatus of claim 4, wherein:
respective ones of the first RF PA and the second RF PA include a number of amplifier slices, the power control inputs of the respective ones of the first RF PA and the second RF PA to enable or disable respective amplifier slices of the respective ones of the first RF PA and the second RF PA to produce the bias current.

6. The apparatus of claim 1, wherein:
when the logic circuitry is to receive control signals including the requested output power level comprising a first requested output power level within a first range of output power levels of the configurable RF PA circuitry, the logic circuitry is to:
set the one or more enable switches to switchably enable the first RF PA;
set the one or more voltage source switches to switchably couple the first voltage source to the voltage bias input of the first RF PA; and
set the power control inputs of the first RF PA to amplify the RF transmit signal to at least substantially the first requested output power level; and
when the logic circuitry is to receive control signals including the requested output power level comprising a second requested output power level within a second range of output power levels of the configurable RF PA circuitry, the logic circuitry is to:
set the one or more enable switches to switchably enable the first RF PA;
set the one or more voltage source switches to switchably couple the second voltage source to the voltage bias input of the first RF PA; and
set the power control inputs of the first RF PA to amplify the RF transmit signal to at least substantially the second requested output power level.

7. The apparatus of claim 6, wherein:
when the logic circuitry is to receive control signals including the requested output power level comprising a third requested output power level within a third range of output power levels of the configurable RF PA circuitry, the logic circuitry is to:
set the one or more enable switches to switchably enable the second RF PA;
set the one or more voltage source switches to switchably couple the second voltage source to the voltage bias input of the second RF PA; and
set the power control inputs of the second RF PA to amplify the RF transmit signal to at least substantially a fourth requested output power level.

8. The apparatus of claim 6, wherein:
when the logic circuitry is to receive control signals including the requested output power level comprising a third requested output power level within a third range of output power levels of the configurable RF PA circuitry, the logic circuitry is to:
set the one or more enable switches to switchably enable the second RF PA;
set the one or more voltage source switches to switchably couple the first voltage source to the voltage bias input of the second RF PA; and
set the power control inputs of the second RF PA to amplify the RF transmit signal to at least substantially the third requested output power level; and
when the logic circuitry is to receive control signals including the requested output power level comprising a fourth requested output power level within a fourth range of output power levels of the configurable RF PA circuitry, the logic circuitry is to:
set the one or more enable switches to switchably enable the second RF PA;
set the one or more voltage source switches to switchably couple the second voltage source to the voltage bias input of the second RF PA; and
set the power control inputs of the second RF PA to amplify the RF transmit signal to at least substantially the fourth requested output power level.

9. The apparatus of claim 1, comprising:
a power source line, the power source line for coupling to a battery voltage source having a battery voltage, the second voltage source comprising the battery voltage source and the second voltage comprising the battery voltage; and
a step-down converter, the step-down converter coupled to the power source line, the step-down converter to convert the battery voltage to a step-down voltage to provide a step-down voltage source, the first voltage source comprising the step-down voltage source and the first voltage comprising the step-down voltage.

10. The apparatus of claim 9, comprising:
a voltage regulator, the voltage regulator coupled to the step-down converter, the voltage regulator to regulate the step-down voltage to provide a regulated step-down voltage source having a regulated step-down voltage.

11. The apparatus of claim 10, wherein:
the configurable RF PA circuitry includes:
a first RF signal chain circuit portion, the first RF signal chain circuit portion coupled between the RF signal input and the first amplifier input of the first RF PA, the first RF signal chain circuit portion supplied at the regulated step-down voltage irrespective of coupling position of the one or more voltage source switches; and
a second RF signal chain circuitry, the second RF signal chain circuit portion coupled between the RF signal input and the second amplifier input of the second RF PA, the second RF signal chain circuit portion supplied at the regulated step-down voltage irrespective of coupling position of the one or more voltage source switches.

12. The apparatus of claim 1, wherein the first amplifier input comprises a first differential amplifier input and the second amplifier input comprises a second differential amplifier input, and wherein:
the configurable RF PA circuitry includes:
a first balun coupled to a first differential amplifier output of the first RF PA; and
a second balun coupled to a second differential amplifier output of the second RF PA,
wherein the one or more voltage source switches is for switchably coupling the one of the first voltage source or the second voltage source to a voltage bias input of one of the first balun or the second balun of the enabled one the first RF PA or the second RF PA.

13. The apparatus of claim 12, comprising:
an integrated circuit (IC) including the configurable RF PA circuitry, the IC including:
a first IC output pin, the first IC output pin coupled to a first output of the first balun; and
a second IC output pin, the second IC output pin coupled to a second output of the second balun.

14. A method comprising:
receiving control signals including a requested output power level for a configurable radio frequency (RF) power amplifier (PA) circuitry, the configurable RF PA circuitry including a first RF PA and a second RF PA, the first RF PA having a first amplifier input coupled to an RF signal input, the second RF PA having a second amplifier input coupled to the RF signal input, the second RF PA in parallel with the first RF PA; and
at least partially responsive to the control signals:
setting one or more enable switches to switchably enable one of the first RF PA or the second RF PA;
setting one or more voltage source switches to switchably couple one of a first voltage source or a second voltage source to a voltage bias input of the enabled one of the first RF PA or the second RF PA, the first voltage source having a first voltage, the second voltage source having a second voltage greater than the first voltage; and
setting power control inputs of the enabled one of the first RF PA or the second RF PA to amplify an RF transmit signal to at least substantially the requested output power level.

15. The method of claim 14, wherein the configurable RF PA circuitry is to operate with a pre-specified output impedance, the control signals comprise input logic level signals received at a look-up table (LUT), and setting the power control inputs comprises:
setting output logic level signals of the LUT to set the power control inputs to produce a bias current in the enabled one of the first RF PA or the second RF PA at least partially responsive to the control signals, the bias current at least partially based on a ratio of the coupled one of the first voltage or the second voltage over the pre-specified output impedance.

16. The method of claim 14, comprising:
converting a battery voltage from a battery voltage source to a step-down voltage to provide a step-down voltage source, the first voltage source comprising the step-down voltage source and the first voltage comprising the step-down voltage, the second voltage source comprising the battery voltage source and the second voltage comprising the battery voltage.

17. The method of claim 16, wherein the configurable RF PA circuitry includes a first RF signal chain circuit portion and a second RF signal chain circuit portion, the first RF signal chain circuit portion coupled between the RF signal input and the first amplifier input of the first RF PA, the second RF signal chain circuit portion coupled between the RF signal input and the second amplifier input of the second RF PA, the method comprising:
regulating the step-down voltage to produce a regulated step-down voltage source; and
supplying power to the first RF signal chain circuitry and the second RF signal chain circuitry via the regulated step-down voltage irrespective of coupling position of the one or more voltage source switches.

18. The method of claim 14, comprising:
at least partially responsive to the control signals including the requested output power level to be a first requested output power level within a first range of output power levels of the configurable RF PA circuitry:
setting the one or more enable switches to enable the first RF PA and disable the second RF PA;
setting the one or more voltage source switches to switchably couple the first voltage source to the voltage bias input of the first RF PA;
setting the power control inputs of the first RF PA to amplify the RF transmit signal to at least substantially the first requested output power level; and
at least partially responsive to the control signals including the requested output power level to be a second requested output power level within a second range of output power levels of the configurable RF PA circuitry:
setting the one or more enable switches to enable the first RF PA and disable the second RF PA;
setting the one or more voltage source switches to switchably couple the second voltage source to the voltage bias input of the first RF PA; and
setting the power control inputs of the first RF PA to amplify the RF transmit signal to at least substantially the second requested output power level.

19. The method of claim 18, comprising:
at least partially responsive to the control signals including the requested output power level to be a third requested output power level within a third range of output power levels of the configurable RF PA circuitry:
setting the one or more enable switches to enable the second RF PA and disable the first RF PA;
setting the one or more voltage source switches to switchably couple the second voltage source to a voltage bias input of the second RF PA; and
setting power control inputs of the second RF PA to amplify the RF transmit signal to at least substantially the third requested output power level.

20. The method of claim 18, comprising:
at least partially responsive to the control signals including the requested output power level to be a third requested output power level within a third range of output power levels of the configurable RF PA circuitry:
setting the one or more enable switches to enable the second RF PA and disable the first RF PA;
setting the one or more voltage source switches to switchably couple the first voltage source to a voltage bias input of the second RF PA; and
setting power control inputs of the second RF PA to amplify the RF transmit signal to at least substantially the third requested output power level; and
at least partially responsive to the control signals including the requested output power level to be a fourth requested output power level within a fourth range of output power levels of the configurable RF PA circuitry:
setting the one or more enable switches to enable the second RF PA and disable the first RF PA;
setting the one or more voltage source switches to switchably couple the second voltage source to the voltage bias input of the second RF PA; and
setting the power control inputs of the second RF PA to amplify the RF transmit signal to at least substantially the fourth requested output power level.

21. The method of claim 14, wherein the first amplifier input comprises a first differential amplifier input, the second amplifier input comprises a second differential amplifier input, the configurable RF PA circuitry includes a first balun coupled to a first differential amplifier output of the first RF PA, the configurable RF PA circuitry includes a second balun coupled to a second differential amplifier output of the second RF PA, and wherein setting the one or more voltage source switches is for switchably coupling one of the first voltage source or the second voltage source to a voltage bias input of one of the first balun or the second balun of the enabled one of the first RF PA or the second RF PA.

22. An apparatus comprising:
an integrated circuit (IC) comprising:
a step-down converter, the step-down converter coupled to a power source line, the power source line for coupling to a battery voltage source having a battery voltage, the step-down converter to convert the battery voltage to a step-down voltage to provide a step-down voltage source;
a configurable radio frequency (RF) power amplifier (PA) circuitry, the configurable RF PA circuitry including:
a first RF PA, the first RF PA including a first amplifier input coupled to an RF signal input, the first RF PA adapted to amplify over a first RF PA output power range when voltage biased at the step-down voltage and over a second RF PA output power range when voltage biased at the battery voltage, the second RF PA output power range greater than the first RF PA output power range;
a second RF PA, the second RF PA including a second amplifier input coupled to the RF signal input, the second RF PA in parallel with the first RF PA, the second RF PA adapted to amplify over a third RF PA output power range when voltage biased at the step-down voltage and over a fourth RF PA output power range when voltage biased at the battery voltage, the fourth RF PA output power range greater than the second RF PA output power range and the third RF PA output power range;
one or more enable switches, the one or more enable switches for switchably enabling one of the first RF PA or the second RF PA to amplify an RF transmit signal; and
ones or more voltage source switches, the one or more voltage source switches for switchably coupling one of the step-down voltage source or the battery voltage source to a voltage bias input of the enabled one the first RF PA or the second RF PA.

23. The apparatus of claim 22, wherein the IC comprising the configurable RF PA circuitry includes:
a logic circuitry, the logic circuitry to receive control signals including a requested output power level for the configurable RF PA circuitry, the logic circuitry to set the one or more enable switches, the one or more voltage source switches, and power control inputs of the enabled one of the first RF PA or the second RF PA to amplify the RF transmit signal to at least substantially the requested output power level.

24. The apparatus of claim 23, wherein the configurable RF PA circuitry is to operate with a pre-specified output impedance, and wherein:
the logic circuitry comprises a look-up table (LUT), the LUT to provide output logic level signals to set the power control inputs to produce a bias current in the enabled one of the first RF PA or the second RF PA at least partially responsive to the control signals comprising input logic level signals, the bias current at least partially based on a ratio of the coupled one of the step-down voltage or the battery voltage over the pre-specified output impedance, and
respective ones of the first RF PA and the second RF PA include a number of amplifier slices, and the power control inputs of the respective ones of the first RF PA and the second RF PA are to enable or disable respective amplifier slices of the respective ones of the first RF PA and the second RF PA to produce the bias current.

25. The apparatus of claim 22, wherein the first amplifier input comprises a first differential amplifier input, the second amplifier input comprises a second differential amplifier input, and the IC comprising the configurable RF PA circuitry includes:
a first balun coupled to a first differential amplifier output of the first RF PA;
a second balun coupled to a second differential amplifier output of the second RF PA;
a first IC output pin, the first IC output pin coupled to a first output of the first balun; and
a second IC output pin, the second IC output pin coupled to a second output of the second balun,
wherein the one or more voltage source switches is for switchably coupling the one of the first voltage source or the second voltage source to a voltage bias input of one of the first balun or the second balun of the enabled one the first RF PA or the second RF PA.

26. The apparatus of claim 25, wherein the IC comprising the configurable RF PA circuitry includes:
a third IC output pin, the third IC output pin to provide a control signal to switchably control an antenna switch for switchably coupling an antenna to one of the first IC output pin through a first impedance matching network or the second IC output pin through a second impedance matching network.

27. The apparatus of claim 22, wherein the IC comprising the configurable RF PA circuitry includes:
a voltage regulator, the voltage regulator coupled to the step-down converter, the voltage regulator to regulate the step-down voltage to provide a regulated step-down voltage source;
a first RF signal chain circuit portion, the first RF signal chain circuit portion coupled between the RF signal input and the first amplifier input of the first RF PA, the first RF signal chain circuit portion supplied at the regulated step-down voltage irrespective of coupling position of the one or more voltage source switches; and
a second RF signal chain circuit portion, the second RF signal chain circuit portion coupled between the RF signal input and the second amplifier input of the second RF PA, the second RF signal chain circuit portion supplied at the regulated step-down voltage irrespective of coupling position of the one or more voltage source switches,
wherein respective ones of the first RF signal chain circuit portion and the second RF signal chain circuit portion include one or more of a line buffer circuitry, a PA buffer circuitry, or a pulse shaping circuitry.
